(19) United States
(12) Patent Application Publication
(10) Pub. No.: US 2023/0299121 A1
(43) Pub. Date: Sep. 21, 2023

(54) DISPLAY DEVICE

(71) Applicant: SAMSUNG DISPLAY CO., LTD., Yongin-si, Gyeonggi-do (KR)

(72) Inventors: Do Yeong PARK, Yongin-si, Gyeonggi-do (KR); Min Kyu WOO, Yongin-si, Gyeonggi-do (KR); Kyung Bae KIM, Yongin-si, Gyeonggi-do (KR)

(21) Appl. No.: 18/041,396

(22) PCT Filed: Jul. 28, 2021
(86) PCT No.: PCT/KR2021/009805

§ 371 Date: Feb. 10, 2023

(30) Foreign Application Priority Data
Aug. 11, 2020 (KR) 10-2020-0100760

(51) Int. Cl. H01L 27/15; H01L 33/24

(52) U.S. Cl. CPC H01L 27/156; H01L 33/24

(57) ABSTRACT

A display device is provided. The display device comprises: a first electrode and a second electrode that are spaced from each other in a first direction; a plurality of light-emitting elements arranged between the first electrode and the second electrode; a pixel circuit including a capacitor that includes first to third capacitor electrodes stacked in order; an interlayer insulation layer arranged between the second capacitor electrode and the third capacitor electrode; a first area overlapping on the first capacitor electrode; and a second area that excludes the first area, wherein the interlayer insulation layer of the first area is thinner than the interlayer insulation layer in the second area.

### CROSS-REFERENCE TO RELATED APPLICATIONS

This application is a U.S. National Phase Patent Application of International Patent Application Number PCT/KR2021/009805, filed on Jul. 28, 2021, which claims priority to Korean Patent Application Number 10-2020-0100760, filed on Aug. 11, 2020, the entire content of all of which is incorporated herein by reference.

### FIELD

The present disclosure relates to a display device.

### BACKGROUND ART

Recently, interest in an information display is increasing. Accordingly, research and development on a display device are continuously being conducted.

### SUMMARY

The present disclosure provides a display device including a capacitor having a large charge capacity in a limited space.

The aspects of the present disclosure are not limited to the aspect mentioned above, and other aspects that are not mentioned may be clearly understood to a person of an ordinary skill in the art using the following description.

A display device according to one or more embodiments for solving the problem includes first and second electrodes spaced apart from each other in a first direction, a plurality of light emitting elements located between the first electrode and the second electrode, a pixel circuit including a capacitor including first to third capacitor electrodes that are sequentially stacked, an interlayer insulating layer located between the second capacitor electrode and the third capacitor electrode, and a first area overlapping the first capacitor electrode and a second area excluding the first area, wherein a thickness of the interlayer insulating layer in the first area is thinner than a thickness of the interlayer insulating layer in the second area.

A width of the first area in the first direction may be substantially the same as a width of the first capacitor electrode in the first direction.

A width of the first area in the first direction may be greater than a width of the second capacitor electrode in the first direction.

A width of the first area in the first direction may be less than a width of the third capacitor electrode in the first direction.

The interlayer insulating layer may include a first insulating layer, and a second insulating layer located on the first insulating layer, and the first insulating layer may include an opening overlapping the first area.

A width of the opening of the first insulating layer in the first direction may be substantially the same as a width of the first capacitor electrode in the first direction.

A width of the opening of the first insulating layer in the first direction may be greater than a width of the second capacitor electrode in the first direction.

The opening of the first insulating layer may expose the second capacitor electrode.

The second insulating layer may be in contact with the second capacitor electrode through the opening of the first insulating layer.

The interlayer insulating layer may include a first insulating layer, and a second insulating layer located on the first insulating layer, and the second insulating layer may include an opening overlapping the first area.

The opening of the second insulating layer may overlap the second capacitor electrode.

A width of the opening of the second insulating layer in the first direction may be substantially the same as a width of the first capacitor electrode in the first direction.

The display device may further include a gate insulating layer located between the first capacitor electrode and the second capacitor electrode, wherein a thickness of the gate insulating layer in the first area may be thinner than a thickness of the gate insulating layer in the second area.

The gate insulating layer may include a plurality of inorganic films, and at least one of the plurality of inorganic films includes an opening overlapping the first area.

A width of the opening of the gate insulating layer in the first direction may be substantially the same as a width of the first capacitor electrode in the first direction.

The first capacitor electrode may be formed of a first conductive layer, the second capacitor electrode may be formed of a second conductive layer, and the display device may further include a semiconductor layer located between the first conductive layer and the second conductive layer.

The first capacitor electrode and the second capacitor electrode may overlap to configure a first capacitor, and the second capacitor electrode and the third capacitor electrode may overlap to configure a second capacitor.

The pixel circuit may include a plurality of transistors that drive the light emitting element, and each of the transistors may include a semiconductor layer located in the second area, a gate electrode located on the semiconductor layer, and a source electrode and a drain electrode located on the gate electrode and respectively connected to the semiconductor layer.

The second capacitor electrode may be formed of the same conductive layer as the gate electrode, and the third capacitor electrode may be formed of the same conductive layer as the source electrode and the drain electrode.

The capacitor may be connected between a node electrically connected to the gate electrode and the first electrode.

Aspects of other embodiments are included in the detailed description and drawings.

According to the embodiments, it is possible to increase a charge capacity of a capacitor by thinly forming a thickness of an insulating layer in a first area in which the capacitor is formed. Accordingly, it is possible to reduce or minimize a capacitance deviation between a gate electrode and a source electrode due to a change in characteristics of a light emitting element, and thus, a short-term afterimage defect due to non-uniform luminance may be reduced or minimized. In addition, because a large charging capacity may be secured in a limited space, an area occupied by a capacitor may be reduced or minimized. That is, an ultra-high resolution display device may be suitably implemented.

Aspect of embodiments of the present disclosure are not limited by what is illustrated in the above, and more various aspects are included in the present specification.

### DESCRIPTION OF THE DRAWINGS

FIG. 1 and FIG. 2 illustrate a perspective view and a cross-sectional view of a light emitting element according to one or more embodiments, respectively.

FIG. 3 and FIG. 4 illustrate a perspective view and a cross-sectional view of a light emitting element according to one or more other embodiments, respectively.

FIG. 5 illustrates a perspective view of a light emitting element according to one or more other embodiments.

FIG. 6 illustrates a cross-sectional view of a light emitting element according to one or more other embodiments.

FIG. 7 illustrates a perspective view of a light emitting element according to one or more other embodiments.

FIG. 8 illustrates a top plan view of a display device according to one or more embodiments.

FIG. 9 illustrates a circuit diagram of an example of the pixel of FIG. 8.

FIG. 10 illustrates a top plan view of an example of the pixels of FIG. 8.

FIG. 11 illustrates a top plan view of an example of a first pixel of the pixels of FIG. 10.

FIG. 12 and FIG. 13 illustrate cross-sectional views taken along the line I-I′ and II-II of FIG. 11.

FIG. 14 to FIG. 17 illustrate cross-sectional views taken along the line III-III′ and IV-IV′ of FIG. 11.

FIG. 18 to FIG. 24 illustrate cross-sectional views of process steps of a manufacturing method of a display device according to one or more embodiments.

### DETAILED DESCRIPTION

Aspects and methods of accomplishing the same may be understood more readily by reference to the following detailed description of preferred embodiments and the accompanying drawings. However, the present disclosure is not limited to the embodiments described hereinafter, and may be embodied in many different forms, and the present disclosure is defined only by the scope of the appended claims.

It will be understood that when an element or a layer is referred to as being “on” another element or layer, it can be directly on another element or layer, or intervening element or layer may also be present. Throughout the specification, the same reference numerals denote the same constituent elements.

Although the terms “first”, “second”, and the like are used to describe various constituent elements, these constituent elements are not limited by these terms.

These terms are used only to distinguish one constituent element from another constituent element. Therefore, the first constituent elements described below may be the second constituent elements within the technical spirit. Singular forms are intended to include plural forms unless the context clearly indicates otherwise.

Hereinafter, embodiments will be described in detail with reference to the accompanying drawings.

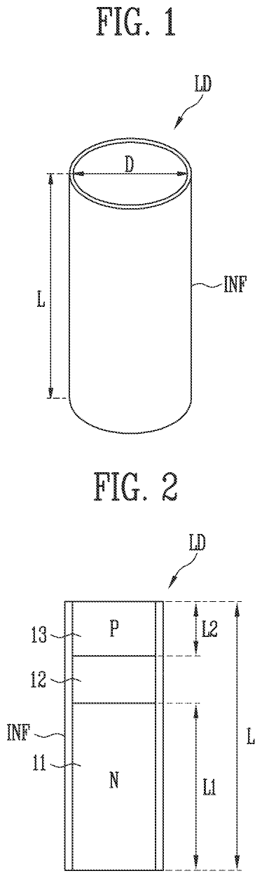

FIG. 1 and FIG. 2 illustrate a perspective view and a cross-sectional view of a light emitting element according to one or more embodiments, respectively. In FIG. 1 and FIG. 2, a cylindrical rod-shaped light emitting element LD is illustrated, but a type and/or shape of the light emitting element LD is not limited thereto.

Referring to FIG. 1 and FIG. 2, the light emitting element LD may include a first semiconductor layer 11 and a second semiconductor layer 13, and an active layer 12 interposed between the first and second semiconductor layers 11 and 13. For example, the light emitting element LD may be configured of a stacked body in which the first semiconductor layer 11, the active layer 12 and the second semiconductor layer 13 are sequentially stacked along one direction.

In some embodiments, the light emitting element LD may be provided to have a rod shape extending along one direction. The light emitting element LD may have one end portion and the other end portion along one direction.

In some embodiments, one of the first and second semiconductor layers 11 and 13 may be located at one end portion of the light emitting element LD, and the other of the first and second semiconductor layers 11 and 13 may be located at the other end portion of the light emitting element LD.

In some embodiments, the light emitting element LD may be a rod-shaped light emitting diode manufactured in a rod shape. Here, the rod shape includes a rod-like shape or a bar-like shape, of which a longitudinal direction is longer than a width direction thereof (that is, with an aspect ratio greater than 1), such as a cylinder or polygonal column, and a shape of a cross section thereof is not particularly limited. For example, the length L of the light emitting element LD may be larger than a diameter D thereof (or a width of a lateral cross-section thereof).

In some embodiments, the light emitting element LD may have a size as small as a nanometer scale to a micrometer scale, for example, a diameter D and/or a length L ranging from about 100 nm to about 10 um. However, the size of the light emitting element LD is not limited thereto. For example, the size of the light emitting element LD may be variously changed according to design conditions of various devices using a light emitting device using the light emitting element LD as a light source, for example, a display device.

The first semiconductor layer 11 may include at least one n-type semiconductor material. For example, the first semiconductor layer 11 may include a semiconductor material of one of InAlGaN, GaN, AlGaN, InGaN, AlN, and InN, and may include a n-type semiconductor material doped with a first conductive dopant such as Si, Ge, Sn, or the like.

The active layer 12 is located on the first semiconductor layer 11, and may be formed to have a single or multi-quantum well structure. In one or more embodiments, a clad layer doped with a conductive dopant may be formed at an upper portion and/or a lower portion of the active layer 12. For example, the clad layer may be formed as an AlGaN layer or an InAlGaN layer. In some embodiments, a material such as AlGaN and AlInGaN may be used to form the active layer 12, and in addition, various materials may form the active layer 12. The active layer 12 may be located between the first semiconductor layer 11 and the second semiconductor layer 13 to be described later.

When a voltage of a threshold voltage or more is applied to respective ends of the light emitting element LD, the light emitting element LD may emit light while electron-hole pairs are combined in the active layer 12. By controlling the light emission of the light emitting element LD by using this principle, the light emitting element LD may be used as a light source for various light emitting devices in addition to pixels of a display device.

The second semiconductor layer 13 is located on the active layer 12, and may include a semiconductor material of a type different from that of the first semiconductor layer 11. For example, the second semiconductor layer 13 may include at least one p-type semiconductor material. For example, the second semiconductor layer 13 may include at least one semiconductor material of InAlGaN, GaN, AlGaN, InGaN, AlN, and InN, and may include a p-type semiconductor material doped with a second conductive dopant such as Mg. However, the material included in the second semiconductor layer 13 is not limited thereto, and the second semiconductor layer 13 may be formed of various materials. In some embodiments, a first length L1 of the first semiconductor layer 11 may be longer than a second length L2 of the second semiconductor layer 13.

In some embodiments, the light emitting element LD may further include an insulating film INF provided on a surface thereof. The insulating film INF may be formed on the surface of the light emitting element LD so as to surround at least an outer circumferential surface of the active layer 12, and may further surround one area of the first and second semiconductor layers 11 and 13.

However, in some embodiments, the insulating film INF may expose respective end portions of the light emitting element LD having different polarities. For example, the insulating film INF does not cover one end of each of the first and second semiconductor layers 11 and 13 located at both ends of the light emitting element LD in the length direction, for example, two flat surfaces (that is, upper and lower surfaces) of the circular cylinder, but may expose it. In some embodiments, the insulating film INF may expose both end portions of the light emitting element LD having different polarities and side portions of the semiconductor layers 11 and 13 adjacent to both end portions.

In some embodiments, the insulating film INF may be formed as a single film or a multifilm (for example, a double film made of an aluminum oxide (AlOx) and a silicon oxide (SiOx)) by including at least one insulating material of a silicon oxide (SiOx), a silicon nitride (SiNx), a silicon oxynitride (SiOxNy), an aluminum oxide (AlOx), and a titanium oxide (TiOx), but is not limited thereto.

In the embodiments, the light emitting element LD may further include an additional component in addition to the first semiconductor layer 11, the active layer 12, the second semiconductor layer 13 and/or the insulating film INF. For example, the light emitting element LD may additionally include one or more of a phosphor layer, an active layer, a semiconductor layer, and/or an electrode layer located on one end side of the first semiconductor layer 11, the active layer 12, and/or the second semiconductor layer 13.

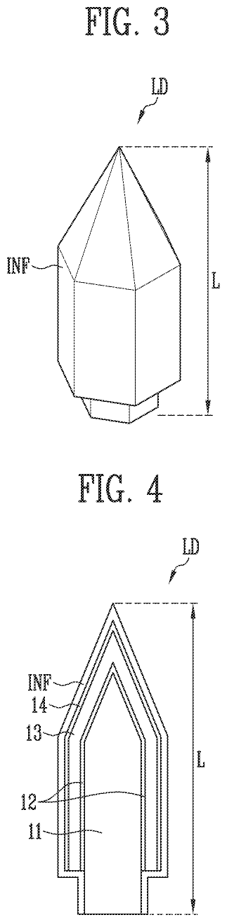

FIG. 3 and FIG. 4 illustrate a perspective view and a cross-sectional view of a light emitting element according to one or more other embodiments, respectively.

Referring to FIG. 3 and FIG. 4, the light emitting element LD according to one or more embodiments includes a first semiconductor layer 11 and a second semiconductor layer 13, and an active layer 12 interposed between the first and second semiconductor layers 11 and 13. In some embodiments, the first semiconductor layer 11 may be located in a central area of the light emitting element LD, and the active layer 12 may be located on the surface of the first semiconductor layer 11 to surround at least one area of the first semiconductor layer 11. In addition, the second semiconductor layer 13 may be located on a surface of the active layer 12 to surround at least one area of the active layer 12.

In addition, the light emitting element LD may further include an electrode layer 14 and/or an insulating film INF, surrounding at least one area of the second semiconductor layer 13. For example, the light emitting element LD may include the electrode layer 14 located on a surface of the second semiconductor layer 13 so as to surround one area of the second semiconductor layer 13, and the insulating film INF located on a surface of the electrode layer 14 so as to surround at least one area of the electrode layer 14. That is, the light emitting element LD according to the above-described embodiments may be implemented to have a core-shell structure including the first semiconductor layer 11, the active layer 12, the second semiconductor layer 13, the electrode layer 14, and the insulating film INF sequentially located from a center to an outer side, and the electrode layer 14 and/or insulating film INF may be omitted in some embodiments.

In one or more embodiments, the light emitting element LD may be provided in a shape of a polygonal pyramid extending in any one direction. For example, at least one area of the light emitting element LD may have a hexagonal horn shape. However, the shape of the light emitting element LD is not limited thereto, and may be variously changed.

When an extending direction of the light emitting element LD is referred to as a length L direction, the light emitting element LD may be provided with one end portion and the other end portion along the length L direction. In some embodiments, one of the first and second semiconductor layers 11 and 13 may be located at one end portion of the light emitting element LD, and the other of the first and second semiconductor layers 11 and 13 may be located at the other end portion of the light emitting element LD.

In one or more embodiments, the light emitting element LD may be a polygonal columnar shape, for example, a micro-light emitting diode having a core-shell structure made of a hexagonal horn shape with both end portions protruding. For example, the light emitting element LD may have a size as small as a nanometer scale to a micrometer scale, for example, a width and/or a length L of a nanometer scale or micrometer scale range. However, the size and/or shape of the light emitting element LD may be variously changed according to design conditions of various devices using the light emitting element LD as a light source, for example, a display device.

In one or more embodiments, both end portions of the first semiconductor layer 11 along the length L direction of the light emitting element LD may have a protruding shape. The protruding shapes of both end portions of the first semiconductor layer 11 may be different from each other. For example, one end portion located at an upper side of both end portions of the first semiconductor layer 11 may have a horn shape contacting one vertex as a width thereof narrows toward an upper portion. In addition, the other end portion located at a lower side of both end portions of the first semiconductor layer 11 may have a polygonal column shape having a constant width, but is not limited thereto. For example, in one or more other embodiments, the first semiconductor layer 11 may have a cross section of a polygonal shape or a step shape, which gradually decreases in width as it goes downward. The shapes of both end portions of the first semiconductor layer 11 may be variously changed according to embodiments, and thus, are not limited to the above-described embodiments.

In some embodiments, the first semiconductor layer 11 may be positioned at a core of the light emitting element LD, that is, at a center (or central area). In addition, the light emitting element LD may be provided to have a shape corresponding to a shape of the first semiconductor layer 11. For example, when the first semiconductor layer 11 has a hexagonal horn shape, the light emitting element LD may have a hexagonal horn shape.

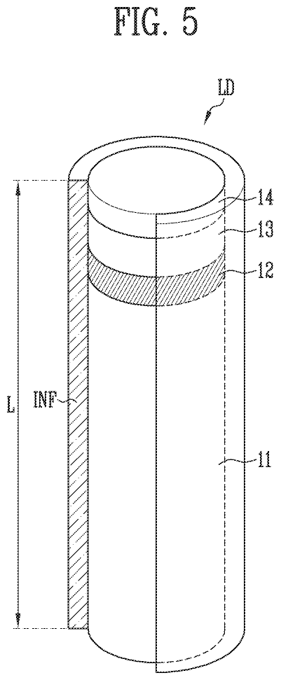

FIG. 5 illustrates a perspective view of a light emitting element according to one or more other embodiments. In FIG. 5, a portion of the insulating film INF is omitted for convenience of description.

Referring to FIG. 5, the light emitting element LD may further include an electrode layer 14 located on the second semiconductor layer 13.

The electrode layer 14 may be an ohmic contact electrode electrically connected to the second semiconductor layer 13, but is not limited thereto. In some embodiments, the electrode layer 14 may be a Schottky contact electrode. The electrode layer 14 may include a metal or a metal oxide, and for example, Cr, Ti, Al, Au, Ni, ITO, IZO, ITZO, and an oxide thereof or an alloys thereof may be used alone or in combination therein. In addition, the electrode layer 14 may be substantially transparent or translucent. Accordingly, light generated by the active layer 12 of the light emitting element LD may pass through the electrode layer 14 to be emitted to the outside of the light emitting element LD.

Although not separately illustrated, in one or more other embodiments, the light emitting element LD may include an electrode layer 14 located on the second semiconductor layer 13, and may further include an electrode layer located on the first semiconductor layer 11.

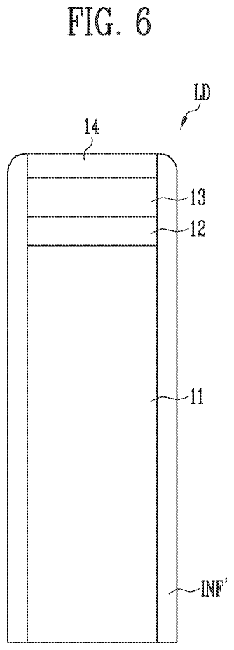

FIG. 6 illustrates a cross-sectional view of a light emitting element according to one or more other embodiments.

Referring to FIG. 6, an insulating film INF′ may have a curved shape in a corner area adjacent to the electrode layer 14. In some embodiments, when the light emitting element LD is manufactured, the curved shape may be formed by etching. In one or more embodiments, even in a light emitting element of one or more other embodiments having the structure further including the electrode layer located on the first semiconductor layer 11, the insulating film INF′ may have a curved shape in an area adjacent to the electrode layer.

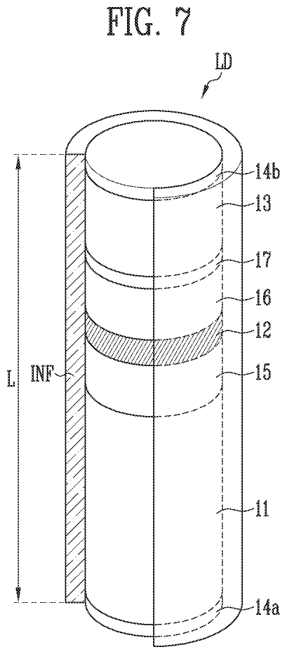

FIG. 7 illustrates a perspective view of a light emitting element according to one or more other embodiments. In FIG. 7, a portion of the insulating film INF is omitted for convenience of description.

First, referring to FIG. 7, the light emitting element LD according to one or more embodiments may include a third semiconductor layer 15 located between the first semiconductor layer 11 and the active layer 12, and a fourth semiconductor layer 16 and a fifth semiconductor layer 17 located between the active layer 12 and the second semiconductor layer 13. The light emitting element LD of FIG. 7 is different from that of the embodiments corresponding to FIG. 1 in that a plurality of semiconductor layers 15, 16, and 17 and electrode layers 14a and 14b are further included, and in that the active layer 12 contains other elements. Except for that, the arrangement and structure of the insulating film INF is substantially the same as that of FIG. 1. In FIG. 7, some of the members are the same as those of FIG. 1, but new reference numerals are denoted for convenience of description. Hereinafter, redundant descriptions will be omitted, and differences from the above-described embodiments will be mainly described.

In the light emitting element LD of FIG. 7, the active layer 12 and other semiconductor layers may be a semiconductor including at least phosphorus (P), respectively. That is, the light emitting element LD according to one or more embodiments may emit red light having a center wavelength band of about 620 nm to about 750 nm. However, it should be understood that the central wavelength band of red light is not limited to the above-described range, and includes all wavelength ranges that may be recognized as red in the art.

For example, in the light emitting element LD according to the embodiments corresponding to FIG. 7, the first semiconductor layer 11 is an n-type semiconductor layer, and when the light emitting element LD emits red light, the first semiconductor layer 11 may include a semiconductor material having the formula InxAlyGa1-x-Yp (0≤x≤1, 0≤y≤1, 0≤x+y≤1). For example, the first semiconductor layer 11 may be any one or more of n-type doped InAlGaP, GaP, AlGaP, InGaP, AlP, and InP. The first semiconductor layer 11 may be doped with an n-type dopant, and for example, the n-type dopant may be Si, Ge, Sn, or the like. In one or more embodiments, the first semiconductor layer 11 may be n-AlGaInP doped with n-type Si. A length of the first semiconductor layer 11 may be about 1.5 μm to about 5 um, but is not limited thereto.

The second semiconductor layer 13 is a p-type semiconductor layer, and when the light emitting element LD emits red light, the second semiconductor layer 13 may include a semiconductor material having the formula InxAlyGa1-x-Yp (0≤x≤1, 0≤y≤1, 0≤x+y≤1). For example, the second semiconductor layer 13 may be any one or more of p-type doped InAlGaP, GaP, AlGaNP, InGaP, AlP, and InP. The second semiconductor layer 13 may be doped with a p-type dopant, and for example, the p-type dopant may be Mg, Zn, Ca, Se, Ba, or the like. In one or more embodiments, the second semiconductor layer 13 may be p-GaP doped with p-type Mg. A length of the second semiconductor layer 13 may be about 0.08 um to about 0.25 um, but is not limited thereto.

The active layer 12 may be located between the first semiconductor layer 11 and the second semiconductor layer 13. As in the active layer 12 of FIG. 1, the active layer 12 of FIG. 7 may also emit light of a corresponding wavelength band by including a material having a single or multiple quantum well structure. For example, when the active layer 12 emits light in a red wavelength band, the active layer 12 may include a material such as AlGaP or AlInGaP. For example, when the active layer 12 has a structure in which a quantum layer and a well layer are alternately stacked in a multi-quantum well structure, the quantum layer may include an inorganic material such as AlGaP or AlInGaP, and the well layer may include a material such as GaP or AlInP. In one or more embodiments, the active layer 12 may emit red light having a central wavelength band of about 620 nm to about 750 nm by including AlGaInP as the quantum layer and AlInP as the well layer.

The light emitting element LD of FIG. 7 may include a clad layer located adjacent to the active layer 12. As shown in the drawing, the third semiconductor layer 15 and the fourth semiconductor layer 16 located between the first semiconductor layer 11 and the second semiconductor layer 13 below and above the active layer 12 may be clad layers, respectively.

The third semiconductor layer 15 may be located between the first semiconductor layer 11 and the active layer 12. The third semiconductor layer 15 may be an n-type semiconductor like the first semiconductor layer 11, and, for example, the third semiconductor layer 15 may include a semiconductor material having the formula InxAlyGa1-x-Yp (0≤x≤1, 0≤y≤1, 0≤x+y≤1). In one or more embodiments, the first semiconductor layer 11 may be n-AlGaInP, and the third semiconductor layer 15 may be n-AlInP. However, it is not limited thereto.

The fourth semiconductor layer 16 may be located between the active layer 12 and the second semiconductor layer 13. The fourth semiconductor layer 16 may be an n-type semiconductor like the second semiconductor layer 13, and for example, the fourth semiconductor layer 16 may include a semiconductor material having the formula InxAlyGa1-x-Yp (0≤x≤1, 0≤y≤1, 0≤x+y≤1). In one or more embodiments, the second semiconductor layer 13 may be p-GaP, and the fourth semiconductor layer 16 may be p-AlInP.

The fifth semiconductor layer 17 may be located between the fourth semiconductor layer 16 and the second semiconductor layer 13. The fifth semiconductor layer 17 may be a p-type doped semiconductor like the second semiconductor layer 13 and the fourth semiconductor layer 16. In some embodiments, the fifth semiconductor layer 17 may function to reduce a difference in lattice constant between the fourth semiconductor layer 16 and the second semiconductor layer 13. That is, the fifth semiconductor layer 17 may be a tensile strain barrier reducing (TSBR) layer. For example, the fifth semiconductor layer 17 may include p-GaInP, p-AlInP, or p-AlGaInP, but is not limited thereto. In addition, lengths of the third semiconductor layer 15, the fourth semiconductor layer 16, and the fifth semiconductor layer 17 may be about 0.08 um to about 0.25 um, but are not limited thereto.

The first electrode layer 14a and the second electrode layer 14b may be located on the first semiconductor layer 11 and the second semiconductor layer 13, respectively. The first electrode layer 14a may be located on a lower surface of the first semiconductor layer 11, and the second electrode layer 14b may be located on an upper surface of the second semiconductor layer 13. However, the present disclosure is not limited thereto, and at least one of the first electrode layer 14a and the second electrode layer 14b may be omitted. For example, in the light emitting element LD of one or more embodiments, the first electrode layer 14a is not located on the lower surface of the first semiconductor layer 11, and only the second electrode layer 14b may be located on the upper surface of the second semiconductor layer 13. The first electrode layer 14a and the second electrode layer 14b may each include at least one of the materials illustrated in the electrode layer 14 of FIG. 5.

The following embodiments will be described as an example to which the light emitting element LD shown in FIG. 1 and FIG. 2 is applied, but a person skilled in the art may apply various types of light emitting elements including the light emitting element LD shown in FIG. 3 to FIG. 7 to embodiments.

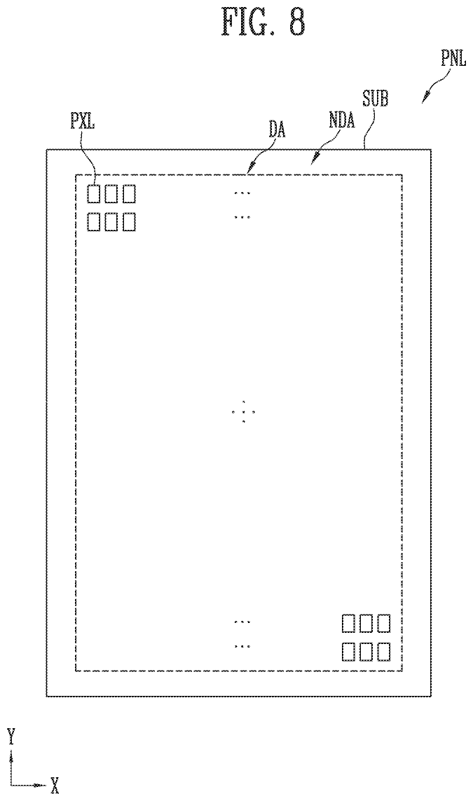

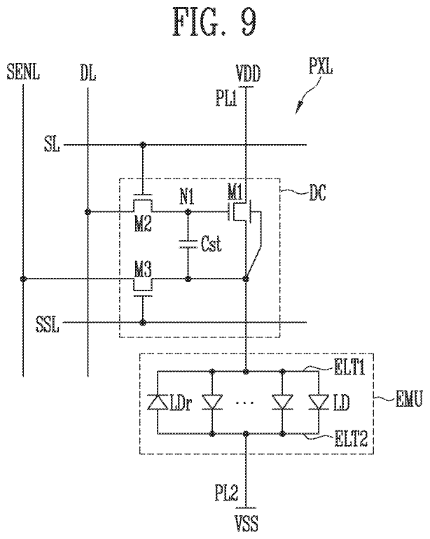

FIG. 8 illustrates a top plan view of a display device according to one or more embodiments.

FIG. 8 illustrates a display device, which is an example of a device that may use the above-described light emitting element LD as a light source, for example, a display panel PNL provided in the display device.

Referring to FIG. 8, the display panel PNL may include a substrate SUB and a pixel PXL (or sub-pixel) located on the substrate SUB. For example, the display panel PNL and the substrate SUB may include a display area DA in which an image is displayed and a non-display area NDA excluding the display area DA.

The substrate SUB may be a rigid substrate or a flexible substrate, and its material or physical properties are not particularly limited. For example, the substrate SUB may be a rigid substrate made of glass or tempered glass, or a flexible substrate made of a thin film made of plastic or metal. In addition, the substrate SUB may be a transparent substrate, but is not limited thereto. For example, the substrate SUB may be a translucent substrate, an opaque substrate, or a reflective substrate.

The display panel PNL and the substrate SUB may include a display area DA that displays a screen, and a non-display area NDA that does not display a screen. The non-display area NDA may be located to surround the display area DA, but is not limited thereto. The display area DA may include a plurality of pixels PXL. The pixels PXL may include at least one light emitting element LD driven by a scan signal and a data signal, for example, at least one light emitting diode according to one of the embodiments of FIG. 1 to FIG. 7. The plurality of light emitting diodes may configure a light source of the pixel PXL.

FIG. 8 illustrates one or more embodiments in which the pixels PXL are arranged in a stripe form in the display area DA, but the present disclosure is not limited thereto, and the pixels PXL may be arranged in various pixel arrangements currently known.

The pixel PXL may be connected to a scan line and a data line, and may also be connected to a high potential power line and a low potential power line. The pixel PXL may emit light with luminance corresponding to the data signal transmitted through the data line in response to the scan signal transmitted through the scan line. The pixels PXL may include substantially the same pixel structure or pixel circuit as each other.

FIG. 9 illustrates a circuit diagram of an example of the pixel of FIG. 8.

Referring to FIG. 9, the pixel PXL may include a light emitting unit EMU, and a pixel driving circuit DC connected thereto to drive the light emitting unit EMU.

The light emitting unit EMU may be interconnected in series between a first power source VDD (or a first driving power source) and a second power source VSS (or a second driving power source). Each light emitting unit EMU may include a plurality of light emitting elements LD connected in parallel between the first power source VDD (or a first power line PL1 to which the first power source VDD is applied) and the second power source VSS (or a second power line PL2 to which the second power source VSS is applied).

The light emitting unit EMU may include a first electrode ELT1 (or a first alignment electrode) connected to the first power source VDD via the pixel driving circuit DC, a second electrode ELT2 (or a second alignment electrode) connected to the second power source VSS, and the plurality of light emitting elements LD connected in parallel in the same direction between the first and second electrodes ELT1 and ELT2. For example, the first electrode ELT1 may be an anode electrode of the light emitting unit EMU, and the second electrode ELT2 may be a cathode electrode thereof.

Each of the light emitting elements LD included in the light emitting unit EMU may include a first end portion connected to the first power source VDD through the first electrode ELT1, and a second end portion connected to the second power source VSS through the second electrode ELT2. The first power source VDD may be set as a high potential power source, and the second power source VSS may be set as a low potential power source. Here, a potential difference between the first and second power sources VDD and VSS may be set to be equal to or greater than a threshold voltage of the light emitting elements LD during a light emitting period of the pixel PXL.

As described above, respective light emitting elements LD connected in parallel in the same direction (for example, a forward direction) between the first electrode ELT1 and the second electrode ELT2 respectively supplied with voltages of different potentials may form respective effective light source.

The light emitting elements LD of the light emitting unit EMU may emit light with luminance corresponding to a driving current supplied through the corresponding pixel driving circuit DC. For example, during each frame period, the pixel driving circuit DC may supply a driving current corresponding to a grayscale value of corresponding frame data to the light emitting unit EMU. The driving current supplied to the light emitting unit EMU may be divided to flow in the light emitting elements LD that are connected in the same direction. Therefore, while each light emitting element LD emits light with a luminance corresponding to the current flowing therein, the light emitting unit EMU may emit light having a luminance corresponding to the driving current.

In some embodiments, the light emitting unit EMU may further include at least one ineffective light source in addition to the light emitting elements LD configuring respective effective light sources. For example, at least reverse direction light emitting element LDr may be further connected between the first and second electrodes ELT1 and ELT2 of the first light emitting unit EMU1. The reverse direction light emitting element LDr is connected in parallel between the first and second electrodes ELT1 and ELT2 together with the light emitting elements LD configuring the effective light sources, but may be connected between the first and second electrodes ELT1 and ELT2 in the opposite direction with respect to the light emitting elements LD. The reverse light emitting element LDr maintains an inactive state even when a driving voltage/predetermined driving voltage (for example, a driving voltage in the forward direction) is applied between the first and second electrodes ELT1 and ELT2, thus a current may not substantially flow in the reverse light emitting element LDr.

The pixel driving circuit DC may include a first transistor M1, a second transistor M2, a third transistor M3, and a storage capacitor Cst.

A first electrode of the first transistor M1 (driving transistor) may be connected to the first power source VDD, and a second electrode thereof may be electrically connected to the first electrode ELT1 of the light emitting unit EMU. A gate electrode of the first transistor M1 may be connected to a first node N1. The first transistor M1 may control an amount of a driving current supplied to the light emitting elements LD in response to a voltage of the first node N1.

In addition, the first transistor M1 may further include a back gate electrode connected to the first electrode ELT1. The back gate electrode is located to overlap the gate electrode with an insulating layer interposed therebetween, and may function as a gate electrode.

A first electrode of the second transistor M2 (switching transistor) may be connected to a data line DL, and a second electrode thereof may be connected to the first node N1. Here, the first electrode and the second electrode of the second transistor M2 may be different electrodes, and for example, when the first electrode is a source electrode, the second electrode may be a drain electrode. A gate electrode of the second transistor M2 may be connected to a scan line SL.

The second transistor M2 is turned on when a scan signal of a voltage at which the first transistor M1 may be turned on (for example, a gate-on voltage) is supplied from the scan line SL, so that it may electrically connect the data line DL and the first node N1. In this case, a data signal of a corresponding frame is supplied to the data line DL, and accordingly, the data signal may be transmitted to the first node Ni. The data signal transmitted to the first node N1 may be stored in the storage capacitor Cst.

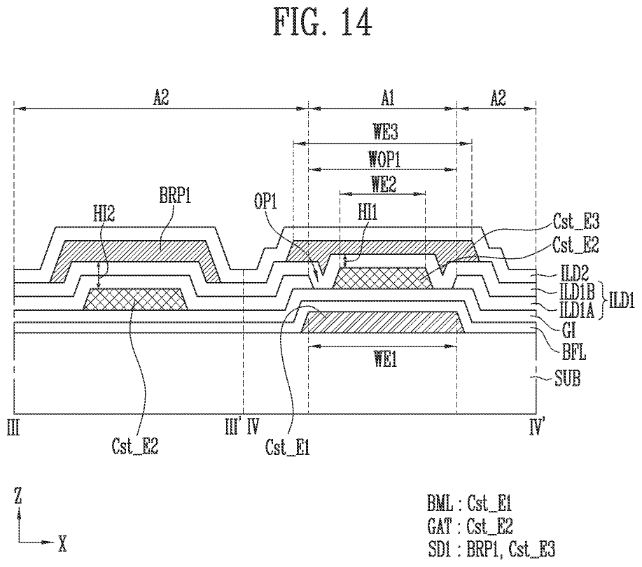

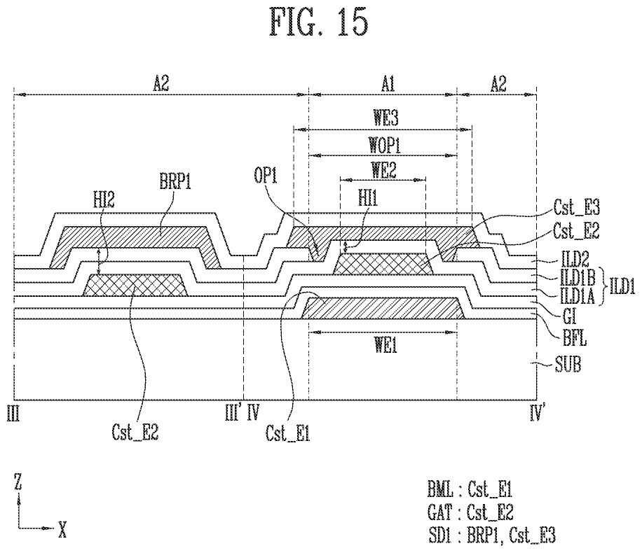

One electrode of the storage capacitor Cst may be connected to the first node N1, and the other electrode thereof may be connected to the first electrode ELT1 (or the second electrode of the first transistor M1) of the light emitting unit EMU1. The storage capacitor Cst may be charged with the voltage corresponding to the data signal supplied to the first node N1, and may maintain the charged voltage until a data signal of a next frame is supplied. Meanwhile, as an area of the pixel PXL decreases in order to realize an ultra-high resolution display device, it is difficult to secure an area of the storage capacitor Cst, and when a capacitance deviation between the gate electrode and the source electrode of the first transistor M1 occurs due to a change in characteristics of the light emitting element LD, a short-term afterimage defect due to luminance non-uniformity may occur. Accordingly, the display device according to one or more embodiments may increase a charging capacity of the storage capacitor Cst in a limited space by thinly forming a thickness of a first interlayer insulating layer (ILD1A in FIG. 14) of a first area (A1 in FIG. 14) in which the storage capacitor Cst is formed. This will be described in detail later with reference to FIG. 14 and the like.

A gate electrode of the third transistor M3 may be connected to a sensing signal line SSL. One electrode of the third transistor M3 may be connected to a sensing line SENL, and the other electrode thereof may be connected to the first electrode ELT1 of the light emitting unit EMU. The third transistor M3 may transmit a voltage value at the first electrode ELT1 of the light emitting unit EMU (or a voltage value at the anode electrode of the light emitting element LD) according to a sensing signal supplied to the sensing signal line SSL during a sensing period to the sensing line SENL. The voltage transmitted through the sensing line SENL may be provided to an external circuit (for example, a timing controller), and the external circuit may extract characteristic information (for example, a threshold voltage of the first transistor M1) of the pixel PXL based on the provided voltage. The extracted characteristic information may be used to convert image data so that a characteristic deviation of the pixel PXL is compensated.

For better understanding and ease of description, the pixel PXL is illustrated as including three transistors and one capacitor in FIG. 9, but is not necessarily limited thereto, and the structure of the pixel driving circuit DC may be variously changed. For example, the pixel driving circuit DC additionally include various transistors such as an initialization transistor for initializing the first node N1, and/or a light emission control transistor for controlling a light emission time of the light emitting element LD, and other circuit elements such as a boosting capacitor for boosting the voltage of the first node N1.

In addition, the transistors included in the pixel driving circuit DC, for example, the first to third transistors M1, M2, and M3, are all illustrated as N-type transistors in FIG. 9, but the present disclosure is not limited thereto. That is, at least one of the first to third transistors M1, M2, and M3 included in the pixel driving circuit DC may be changed to a P-type transistor.

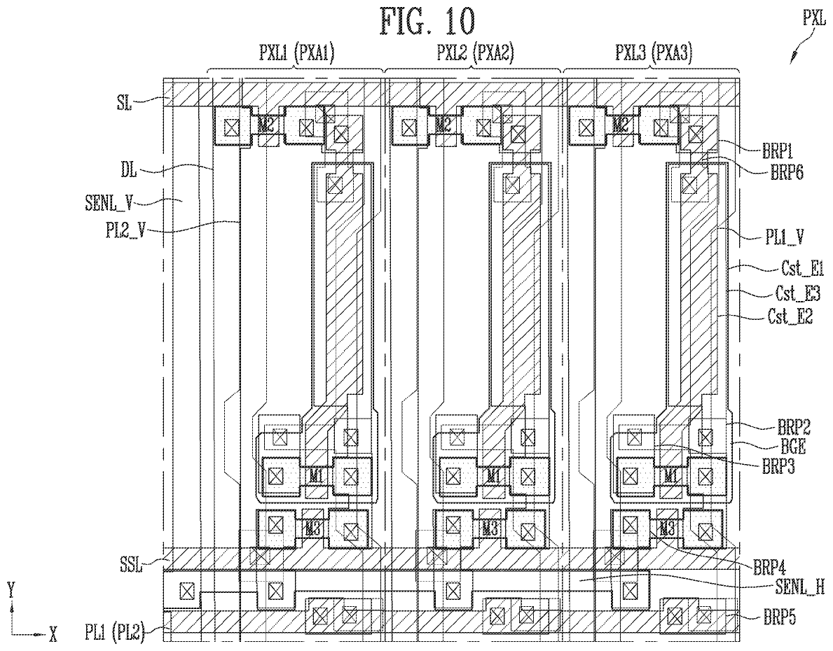

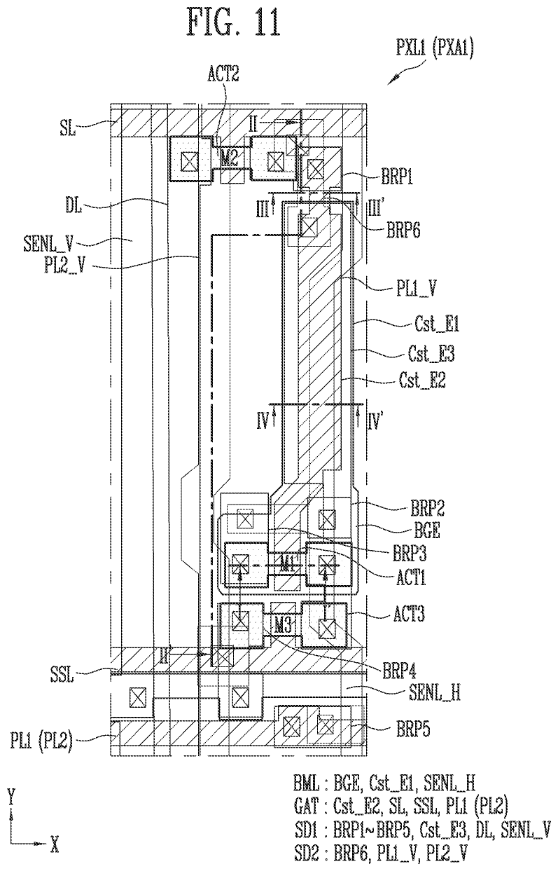

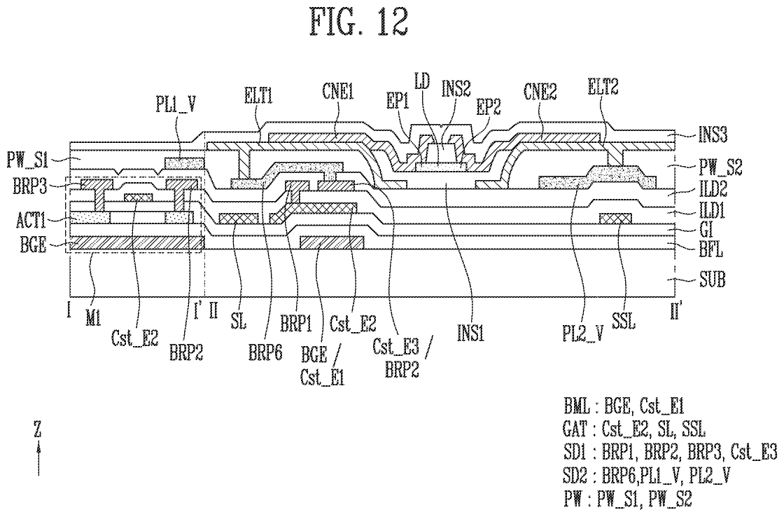

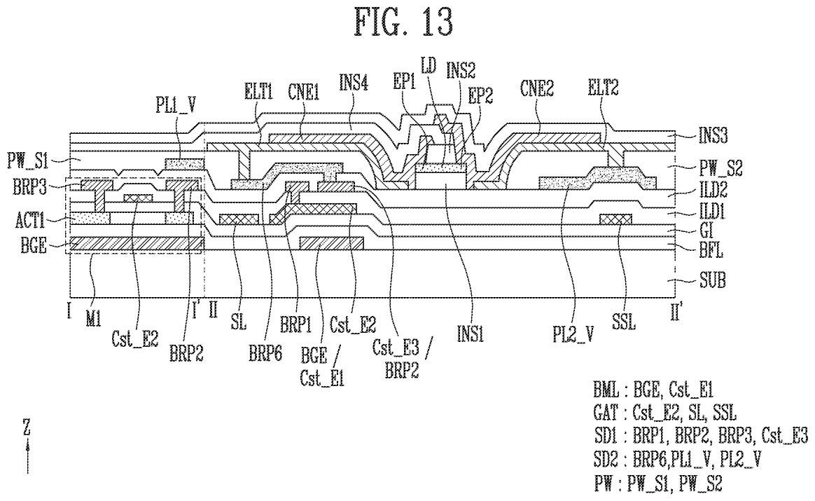

FIG. 10 illustrates a top plan view of an example of the pixels of FIG. 8. FIG. 10 illustrates a structure of the pixel PXL based on the pixel driving circuit (DC in FIG. 9) for driving the light emitting element LD. FIG. 11 illustrates a top plan view of an example of a first pixel of the pixels of FIG. 10. FIG. 12 and FIG. 13 illustrate cross-sectional views taken along the line I-I′ and II-II′ of FIG. 11.

First, referring to FIG. 10, the pixel PXL may include a first pixel PXL1 (or a first pixel area PXA1), a second pixel PXL2 (or a second pixel area PXA2), and a third pixel PXL3 (or a third pixel area PXA3). The first pixel PXL1, the second pixel PXL2, and the third pixel PXL3 may configure one unit pixel.

In some embodiments, the first to third pixels PXL1, PXL2, and PXL3 may emit light in different respective colors. For example, the first pixel PXL1 may be a red pixel emitting light in red, the second pixel PXL2 may be a green pixel emitting light in green, and the third pixel PXL3 may be a blue pixel emitting light in blue. However, the color, type, and/or number of pixels configuring the unit pixel is not particularly limited, and, for example, the color of light emitted by each pixel may be variously changed. In some embodiments, the first to third pixels PXL1, PXL2, and PXL3 may emit light in the same color. For example, the first to third pixels PXL1, PXL2, and PXL3 may be blue pixels emitting blue light. Because the first pixel PXL1, the second pixel PXL2, and the third pixel PXL3 may be substantially the same as or similar to each other, hereinafter, the first pixel PXL1, the second pixel PXL2, and the third pixel PXL3 will be inclusively described based on the first pixel PXL1.

Referring to FIG. 11 and FIG. 12, the first pixel PXL1 may include a first conductive layer BML, a buffer layer BFL, a semiconductor layer, a gate insulating layer GI, a second conductive layer GAT, a first interlayer insulating layer ILD1, a third conductive layer SD1, a second interlayer insulating layer ILD2, a fourth conductive layer SD2, and a passivation layer PW, located on/above a substrate SUB.

The first conductive layer BML may include a back gate electrode BGE, a first capacitor electrode Cst_E1, and a horizontal sensing line SENL_H.

The back gate electrode BGE may entirely overlap with the first transistor M1. The back gate electrode BGE may be substantially the same as the back gate electrode described with reference to FIG. 9.

The first capacitor electrode Cst_E1 may extend in a second direction (Y-axis direction) from the back gate electrode BGE. The first capacitor electrode Cst_E1 may configure the other electrode of the storage capacitor Cst described with reference to FIG. 9.

The horizontal sensing line SENL_H may be spaced apart from the back gate electrode BGE, and may be located below the first pixel area PXA1 in a plan view. The horizontal sensing line SENL_H may extend in a first direction (X-axis direction), and may extend across the first pixel area PXA1, the second pixel area PXA2, and the third pixel area PXA3 as shown in FIG. 10. The first pixel PXL1, the second pixel PXL2, and the third pixel PXL3 may be connected to one horizontal sensing line SENL_H.

The first conductive layer BML may include one or more of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu). The first conductive layer BML may have a single-filmed or multi-filmed structure.

The buffer layer BFL may be located on a front surface of the substrate SUB. The buffer layer BFL may reduce or prevent diffusion of impurity ions, may reduce or prevent penetration of moisture or external air, and may perform a surface planarization function. The buffer layer BFL may include a silicon nitride (SiNx), a silicon oxide (SiNx), or a silicon oxynitride (SiOxNy). The buffer layer BFL may be omitted depending on a type or process condition of the substrate SUB.

The semiconductor layer may be located on the buffer layer BFL (or the substrate SUB). The semiconductor layer may be an active layer forming channels of the first to third transistors M1, M2, and M3.

The semiconductor layer may include first to third semiconductor patterns ACT1, ACT2, and ACT3 spaced apart from each other.

The first semiconductor pattern ACT1 may configure a channel of the first transistor M1, the second semiconductor pattern ACT2 may configure a channel of the second transistor M2, and the third semiconductor pattern ACT3 may configure a channel of the third transistor M3.

Each of the first to third semiconductor patterns ACT1, ACT2, and ACT3 may include a source area and a drain area contacting the first transistor electrode (or source electrode) and the second transistor electrode (or drain electrode). An area between the source area and the drain area may be the channel area.

The semiconductor layer may include an oxide semiconductor. The channel area may be an intrinsic semiconductor that is not doped with an impurity. The source area and drain area may be a semiconductor pattern doped with an impurity. As the impurity, an n-type impurity may be used. In some embodiments, the semiconductor layer may include a silicon semiconductor. For example, the semiconductor layer may be a semiconductor pattern made of a polysilicon, an amorphous silicon, a low temperature poly silicon (LTPS), or the like.

The gate insulating layer GI may be located on the semiconductor layer and the buffer layer BFL (or the substrate SUB). The gate insulating layer GI may be substantially entirely located on the substrate SUB.

The gate insulating layer GI may include an inorganic insulating material such as a silicon compound or a metal oxide. For example, the gate insulating layer GI may include a silicon oxide (SiOx), a silicon nitride (SiNx), a silicon oxynitride (SiOxNy), an aluminum oxide (AlOx), a tantalum oxide (TaOx), a hafnium oxide (HfOx), a zirconium oxide (ZrOx), a titanium oxide (TiOx), or a combination thereof. The gate insulating layer GI may be a single film or a multifilm formed of a stacked film of different materials.

The second conductive layer GAT may be located on the gate insulating layer GI. The second conductive layer GAT may include a scan line SL, a second capacitor electrode Cst_E2, a sensing signal line SSL, and a first power line PL1 (and/or a second power line PL2).

The scan line SL extends in the first direction (X-axis direction), and may extend to another unit pixel area. The scan line SL may be located at an uppermost side of the first pixel area PXA1. The scan line SL overlaps the second semiconductor pattern ACT2, and may configure a gate electrode of the second transistor M2.

The second capacitor electrode Cst_E2 may extend in the second direction (Y-axis direction). The second capacitor electrode Cst_E2 overlaps the first capacitor electrode Cst_E1, and may configure one electrode of the storage capacitor (Cst in FIG. 9). In addition, the second capacitor electrode Cst_E2 overlaps the first semiconductor pattern ACT1, and may configure a gate electrode of the first transistor M1.

The sensing signal line SSL extends in the first direction (X-axis direction), and may extend to another unit pixel area. The sensing signal line SSL overlaps the third semiconductor pattern ACT3, and may configure a gate electrode of the third transistor M3.

The first power line PL1 and/or the second power line PL2 may extend in the first direction (X-axis direction) and may be located in adjacent pixel areas in the same row. For better understanding and ease of description, the first power line PL1 and the second power line PL2 are shown simultaneously in FIG. 10 and FIG. 11, but the first power line PL1 and the second power line PL2 may be alternately located in each pixel row along the second direction (Y-axis direction). In this case, the first power line PL1 and/or the second power line PL2 may be located at a lowermost side of the first pixel area PXA1 in a plan view. That is, the first power line PL1 may be located at a lowermost side of a first pixel row, and the second power line PL2 may be located at a lowermost side of a second pixel row. However, the location of the first power line PL1 and the second power line PL2 is not limited thereto, and may be changed to various layouts.

The second conductive layer GAT may include one or more of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu). The second conductive layer GAT may have a single-filmed or multi-filmed structure.

The first interlayer insulating layer ILD1 may be located on the second conductive layer GAT, and may be substantially and entirely located on the substrate SUB. The first interlayer insulating layer ILD1 may serve to insulate the second conductive layer GAT and the third conductive layer SD1.

The first interlayer insulating layer ILD1 may include an inorganic insulating material such as a silicon oxide (SiOx), a silicon nitride (SiNx), a silicon oxynitride (SiOxNy), a hafnium oxide (HfOx), an aluminum oxide (AlOx), a titanium oxide (TiOx), a tantalum oxide (TaOx), and a zinc oxide (ZnOx). However, it is not limited thereto, and the second insulating layer ILD2 may include an organic insulating material such as a polyacrylates resin, an epoxy resin, a phenolicresin, a polyamides resin, a polyimides rein, an unsaturated polyesters resin, a poly phenylenethers resin, a polyphenylenesulfides resin, or benzocyclobutene (BCB). The first interlayer insulating layer ILD1 may be a single film or a multifilm formed of a stacked film of different materials.

The third conductive layer SD1 may be located on the first interlayer insulating layer ILD1. The third conductive layer SD1 may include a third capacitor electrode Cst_E3, a data line DL, a vertical sensing line SENL_V, and first to fifth bridge patterns BRP1, BRP2, BRP3, BRP4, and BRP5.

The third capacitor electrode Cst_E3 may be located to overlap the second capacitor electrode Cst_E2 (and the first capacitor electrode Cst_E1). The third capacitor electrode Cst_E3 may configure the other electrode of the storage capacitor Cst together with the first capacitor electrode Cst_E1. That is, the storage capacitor Cst includes a first capacitor configured by the second capacitor electrode Cst_E2 and the first capacitor electrode Cst_E1, and a second capacitor configured by the second capacitor electrode Cst_E2 and the third capacitor electrode Cst_E3, and the first capacitor and the second capacitor may be connected in parallel to each other. The charging capacity of the storage capacitor Cst may be secured in a limited space through the overlapping structure of the first capacitor electrode Cst_E1, the second capacitor electrode Cst_E2, and the third capacitor electrode Cst_E3. This will be described in detail with reference to FIG. 14 to FIG. 17.

FIG. 14 to FIG. 17 illustrate cross-sectional views taken along the line and IV-IV′ of FIG. 11. FIG. 14 to FIG. 17 illustrate only the first conductive layer BML, the second conductive layer GAT, and the third conductive layer SD1 for better understanding and ease of description.

Referring to FIG. 14, the storage capacitor Cst may include the first to third capacitor electrodes Cst_E1, Cst_E2, and Cst_E3 that are sequentially stacked. The buffer layer BFL and/or the gate insulating layer GI may be located between the first capacitor electrode Cst_E1 and the second capacitor electrode Cst_E2, and the first interlayer insulating layer ILD1 may be located between the second capacitor electrode Cst_E2 and the third capacitor electrode Cst_E3.

The pixel PXL may include a first area A1 in which the storage capacitor Cst is formed and a second area A2 excluding the first area A1. The first area A1 may overlap the first capacitor electrode Cst_E1, the second capacitor electrode Cst_E2, and/or the third capacitor electrode Cst_E3.

A width in the first direction (X-axis direction) of the first area A1 may be substantially the same as a width WE1 in the first direction (X-axis direction) of the first capacitor electrode Cst_E1. In addition, the width in the first direction (X-axis direction) of the first area A1 may be greater than a width WE2 in the first direction (X-axis direction) of the second capacitor electrode Cst_E2. In addition, the width in the first direction (X-axis direction) of the first area A1 may be less than a width WE3 in the first direction (X-axis direction) of the third capacitor electrode Cst_E3. That is, the third capacitor electrode Cst_E3 may be located to cover the first capacitor electrode Cst_E1 and the second capacitor electrode Cst_E2 that are located thereunder. In this case, it is possible to reduce or prevent formation of parasitic capacitance with the adjacent conductive layer.

In one or more embodiments, a thickness HI1 of the first interlayer insulating layer ILD1 in the first area A1 may be thinner than a thickness HI2 of the first interlayer insulating layer ILD1 in the second area A2. Here, the thickness HI1 of the first interlayer insulating layer ILD1 in the first area A1 may mean a thickness in the third direction (Z-axis direction) from an upper surface of the second capacitor electrode Cst_E2 to a lower surface of the third capacitor electrode Cst_E3. The first interlayer insulating layer ILD1 of the first area A1 may correspond to a dielectric of the storage capacitor Cst. Accordingly, by thinly forming the thickness HI1 of the first interlayer insulating layer ILD1 in the first area A1, the charging capacity of the storage capacitor Cst may be increased. Accordingly, it is possible to reduce or minimize a capacitance deviation between the gate electrode and the source electrode due to a change in characteristics of the light emitting element LD, and thus, a short-term afterimage defect due to non-uniform luminance may be reduced or minimized.

In one or more embodiments, the first interlayer insulating layer ILD1 may include a first insulating layer ILD1A and a second insulating layer ILD1B. The first insulating layer ILD1A may include a first opening OP1 overlapping the first area A1. That is, the first insulating layer ILD1A may be partially removed in the first area A1 to expose the second capacitor electrode Cst_E2 located thereunder. The second capacitor electrode Cst_E2 exposed by the first opening OP1 of the first insulating layer ILD1A may be in direct contact with the second insulating layer ILD1B. As the first insulating layer ILD1A is partially removed in the first area A1, the thickness HI1 of the first interlayer insulating layer ILD1 in the first area A1 may be thinly formed to increase the charging capacity of the storage capacitor Cst. In addition, because a large charging capacity may be secured in a limited space, an area occupied by the storage capacitor Cst may be reduced or minimized. That is, an ultra-high resolution display device may be suitably implemented.

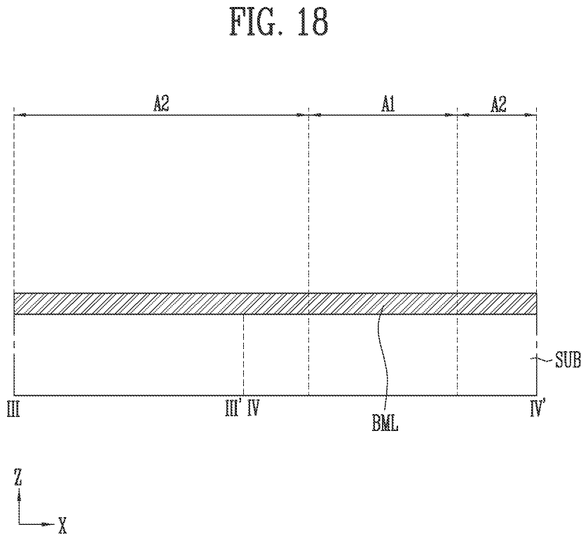

A width in the first direction (X-axis direction) of the first opening OP1 of the first insulating layer ILD1A may be substantially the same as the width WE1 in the first direction (X-axis direction) of the first capacitor electrode Cst_E1. For example, the first opening OP1 of the first insulating layer ILD1A may be patterned by using the same mask as a mask used to form the first capacitor electrode Cst_E1. This will be described in detail later with reference to FIG. 18 to FIG. 24. In addition, the width in the first direction (X-axis direction) of the first opening OP1 of the first insulating layer ILD1A may be greater than the width WE2 in the first direction (X-axis direction) of the second capacitor electrode Cst_E2. In addition, the width in the first direction (X-axis direction) of the first opening OP1 of the first insulating layer ILD1A may be less than the width WE3 in the first direction (X-axis direction) of the third capacitor electrode Cst_E3. Meanwhile, FIG. 14 illustrates the case in which the first insulating layer ILD1A includes the first opening OP1, but the present disclosure is not necessarily limited thereto.

Referring to FIG. 15, the first insulating layer ILD1A covers the second capacitor electrode Cst_E2, while the second insulating layer ILD1B may include the first opening OP1 overlapping the first area A1. The first opening OP1 of the second insulating layer ILD1B may be formed to overlap the second capacitor electrode Cst_E2. That is, the second insulating layer ILD1B may be partially removed in the first area A1 to expose the first insulating layer ILD1A located thereunder. As the second insulating layer ILD1B is partially removed in the first area A1 so that the thickness HI1 of the first interlayer insulating layer ILD1 of the first area A1 becomes thinner, the storage capacitor Cst may have a large charging capacity in a limited space. Accordingly, as described above, it is possible to suitably implement an ultra-high resolution display device by concurrently reducing or preventing a short-term after-image defect caused by a change in characteristics of the light emitting element LD and reducing or minimizing the area occupied by the storage capacitor Cst.

A width in the first direction (X-axis direction) of the first opening OP1 of the second insulating layer ILD1B may be substantially the same as the width WE1 in the first direction (X-axis direction) of the first capacitor electrode Cst_E1. For example, the first opening OP1 of the second insulating layer ILD1B may be patterned by using the same mask as a mask used to form the first capacitor electrode Cst_E1. In addition, the width in the first direction (X-axis direction) of the first opening OP1 of the second insulating layer ILD1B may be greater than the width WE2 in the first direction (X-axis direction) of the second capacitor electrode Cst_E2. In addition, the width in the first direction (X-axis direction) of the first opening OP1 of the second insulating layer ILD1B may be less than the width WE3 in the first direction (X-axis direction) of the third capacitor electrode Cst_E3. Meanwhile, FIG. 14 and FIG. 15 illustrate the case in which the thickness of the first interlayer insulating layer ILD1 located between the second capacitor electrode Cst_E2 and the third capacitor electrode Cst_E3 is thinly formed, but the present disclosure is not necessarily limited thereto.

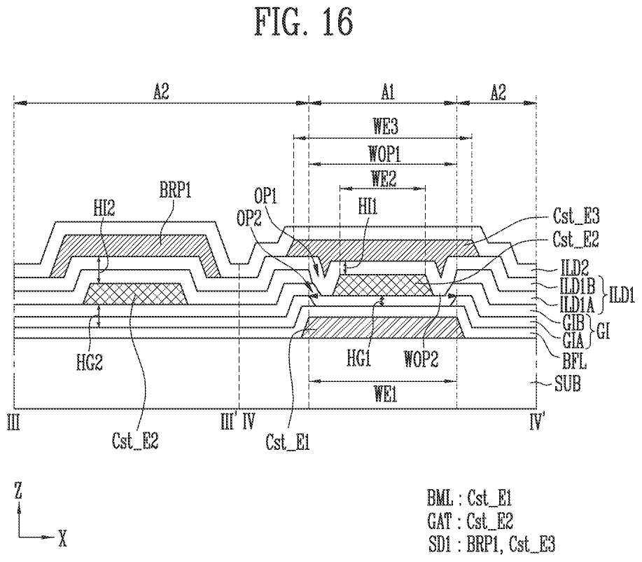

Referring to FIG. 16, a thickness HG1 of the gate insulating layer GI in the first area A1 may be thinner than a thickness HG2 of the gate insulating layer GI in the second area A2. The gate insulating layer GI may include a first gate insulating layer GIA and a second gate insulating layer GIB. The first gate insulating layer GIA may include a second opening OP2 overlapping the first area A1. That is, the first gate insulating layer GIA may be partially removed in the first area A1 to expose the buffer layer BFL located thereunder. The buffer layer BFL exposed by the second opening OP2 of the first gate insulating layer GIA may be in direct contact with the second gate insulating layer GIB. As the first gate insulating layer GIA is partially removed in the first area A1 so that the thickness HG1 of the gate insulating layer GI in the first area A1 becomes thinner, the charging capacity of the storage capacitor Cst may be increased. Accordingly, as described above, it is possible to suitably implement an ultra-high resolution display device by concurrently reducing or preventing a short-term after-image defect caused by a change in characteristics of the light emitting element LD and reducing or minimizing the area occupied by the storage capacitor Cst.

A width in the first direction (X-axis direction) of the second opening OP2 of the first gate insulating layer GIA may be substantially the same as the width WE1 in the first direction (X-axis direction) of the first capacitor electrode Cst_E1. In addition, the width in the first direction (X-axis direction) of the second opening OP2 of the first gate insulating layer GIA may be substantially the same as the width in the first direction (X-axis direction) of the first opening OP1 of the first interlayer insulating layer ILD1 described above. For example, the second opening OP2 of the first gate insulating layer GIA may be patterned by using the same mask as the mask used to form the first opening OP1 of the first capacitor electrode Cst_E1 and/or the first interlayer insulating layer ILD1. In addition, the width in the first direction (X-axis direction) of the second opening OP2 of the first gate insulating layer GIA may be greater than the width WE2 in the first direction (X-axis direction) of the second capacitor electrode Cst_E2. In addition, the width in the first direction (X-axis direction) of the second opening OP2 of the first gate insulating layer GIA may be less than the width WE3 in the first direction (X-axis direction) of the third capacitor electrode Cst_E3. Meanwhile, in one or more embodiments, the second gate insulating layer GIB may include the second opening OP2 in a range in which a distance between the first capacitor electrode Cst_E1 and the second capacitor electrode Cst_E2 may be reduced.

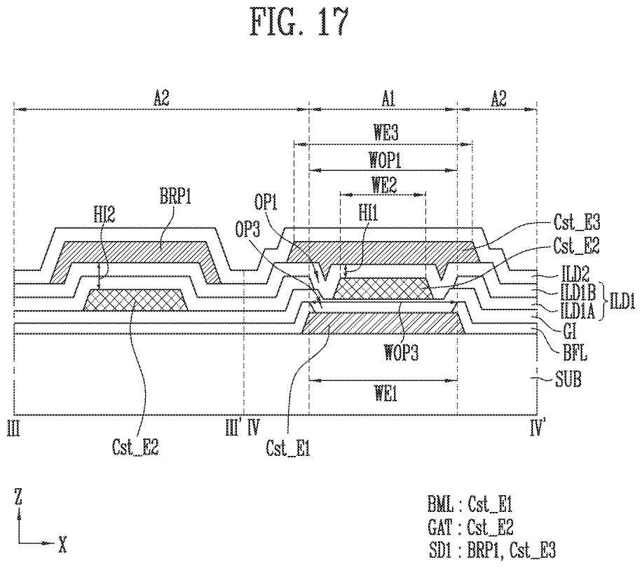

In addition, as shown in FIG. 17, the buffer layer BFL may include a third opening OP3 overlapping the first area A1. That is, the buffer layer BFL may be partially removed in the first area A1 to expose the first capacitor electrode Cst_E1 located thereunder. The first capacitor electrode Cst_E1 exposed by the third opening OP3 of the buffer layer BFL may be in direct contact with the gate insulating layer GI. As the buffer layer BFL is partially removed in the first area A1, the charging capacity of the storage capacitor Cst may be increased. That is, it is possible to reduce or minimize a capacitance deviation between the gate electrode and the source electrode due to a change in characteristics of the light emitting element LD, and thus, a short-term afterimage defect due to non-uniform luminance may be reduced or minimized. In addition, as described above, because a large charging capacity may be secured in a limited space, the area occupied by the storage capacitor Cst may be reduced or minimized to suitably implement an ultra-high resolution display device.

A width in the first direction (X-axis direction) of the third opening OP3 of the buffer layer BFL may be substantially the same as the width WE1 in the first direction (X-axis direction) of the first capacitor electrode Cst_E1. In addition, the width in the first direction (X-axis direction) of the third opening OP3 of the buffer layer BFL may be substantially the same as the width in the first direction (X-axis direction) of the first opening OP1 of the first interlayer insulating layer ILD1 described above. For example, the third opening OP3 of the buffer layer BFL may be patterned by using the same mask as the mask used to form the first opening OP1 of the first capacitor electrode Cst_E1 and/or the first interlayer insulating layer ILD1. In addition, the width in the first direction (X-axis direction) of the third opening OP3 of the buffer layer BFL may be greater than the width WE2 in the first direction (X-axis direction) of the second capacitor electrode Cst_E2. In addition, the width in the first direction (X-axis direction) of the third opening OP3 of the buffer layer BFL may be less than the width WE3 in the first direction (X-axis direction) of the third capacitor electrode Cst_E3.

Referring again to FIG. 11, the data line DL extends in the second direction (Y-axis direction), and may extend to another unit pixel area. The data line DL overlaps a partial area of the second semiconductor pattern ACT2 (or the source area of the second transistor M2), and may be connected to a partial area of the second semiconductor pattern ACT2 exposed through a contact hole. A portion of the data line DL may configure the first transistor electrode of the second transistor M2.

The vertical sensing line SENL_V extends in the second direction (Y-axis direction), and may extend to another unit pixel area. The vertical sensing line SENL_V is located at the left side of the data line DL, and as shown in FIG. 10, it may be located for each unit pixel including the first to third pixels PXL1, PXL2, and PXL3. The vertical sensing line SENL_V overlaps the horizontal sensing line SENL_H, and may be connected to the horizontal sensing line SENL_H exposed through a contact hole.

The first bridge pattern BRP1 overlaps a partial area of the second semiconductor pattern ACT2 (or the source area of the second transistor M2), and is connected to a partial area of the second semiconductor pattern ACT2 exposed through a contact hole, and may configure the second transistor electrode of the second transistor M2. In addition, the first bridge pattern BRP1 overlaps the second capacitor electrode Cst_E2, and may be connected to the second capacitor electrode Cst_E2 through a contact hole. Accordingly, the first transistor electrode of the first transistor M1 may be connected to the second capacitor electrode Cst_E2 (that is, one electrode of the storage capacitor (Cst in FIG. 9)).

The second bridge pattern BRP2 extends downward from the third capacitor electrode Cst_E3, and may overlap a partial area of the first semiconductor pattern ACT1 (or the drain area of the first transistor M1) and a partial area of the third semiconductor pattern ACT3 (or the source area of the third transistor M3). The second bridge pattern BRP2 is connected to a partial area of the first semiconductor pattern ACT1 exposed through a contact hole, and may configure the first transistor electrode of the first transistor M1. In addition, the second bridge pattern BRP2 is connected to a partial area of the third semiconductor pattern ACT3 exposed through a contact hole, and may configure the first transistor electrode of the third transistor M3.

In addition, the second bridge pattern BRP2 may be connected to the first capacitor electrode Cst_E1 exposed through a contact hole. The second bridge pattern BRP2 is integrally formed with the third capacitor electrode Cst_E3, so the third capacitor electrode Cst_E3 is connected to the first capacitor electrode Cst_E1, and may configure the other electrode of the storage capacitor (Cst in FIG. 9).

The third bridge pattern BRP3 overlaps a partial area of the first semiconductor pattern ACT1 (or the drain area of the first transistor M1), and is connected to a partial area of the first semiconductor pattern ACT1 exposed through a contact hole, and may configure the second transistor electrode of the first transistor M1.

The fourth bridge pattern BRP4 overlaps a partial area of the third semiconductor pattern ACT3 (or the drain area of the third transistor M3), and is connected to a partial area of the third semiconductor pattern ACT3 exposed through a contact hole, and may configure the second transistor electrode of the third transistor M3. In addition, the fourth bridge pattern BRP4 overlaps the horizontal sensing line SENL_H, and may be connected to the horizontal sensing line SENL_H through a contact hole. Accordingly, the third transistor M3 may be connected to the vertical sensing line SENL_V through the horizontal sensing line SENL_H.

The fifth bridge pattern BRP5 overlaps the first power line PL1 (and/or the second power line PL2), and may be connected to the first power line PL1 (and/or the second power line PL2) through a contact hole.

Similar to the second conductive layer GAT, the third conductive layer SD1 may include one or more of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu). The third conductive layer SD1 may have a single-filmed or multi-filmed structure.

The second interlayer insulating layer ILD2 is located on the third conductive layer SD1, and may be substantially located on the entire surface of the substrate SUB. The second interlayer insulating layer ILD2 may serve to insulate the third conductive layer SD1 and the fourth conductive layer SD2.

Similar to the first interlayer insulating layer ILD1, the second interlayer insulating layer ILD2 may include an inorganic insulating material, and may be a single film or a multifilm formed of a stacked film of different materials.

The fourth conductive layer SD2 may be located on the second interlayer insulating layer ILD2. The fourth conductive layer SD2 may include a first vertical power line PL1_V, a second vertical power line PL2_V, and a sixth bridge pattern BRP6.

The first vertical power line PL1_V extends in the second direction (Y-axis direction), and may extend to another unit pixel area. The first vertical power line PL1_V includes a protrusion overlapping the third bridge pattern BRP3, and may be connected to the third bridge pattern BRP3 through a contact hole (and the protrusion). Accordingly, the first vertical power line PL1_V may be connected to the first transistor M1 through the third bridge pattern BRP3.

In addition, the first vertical power line PL1_V overlaps the fifth bridge pattern BRP5, and may be connected to the fifth bridge pattern BRP5 through a contact hole. Accordingly, the first vertical power line PL1_V may be connected to the first power line PL1 through the fifth bridge pattern BRP5. Accordingly, the first vertical power line PL1_V and the first power line PL1 may have a mesh structure in the entire display device.

The second vertical power line PL2_V extends in the second direction (Y-axis direction), and may extend to another unit pixel area. The second vertical power line PL2_V may be connected to a second electrode (ELT2 of FIG. 12), to be described later, through a contact hole.

The sixth bridge pattern BRP6 may overlap the third capacitor electrode Cst_E3. The sixth bridge pattern BRP6 may be connected to the third capacitor electrode Cst_E3 exposed through a contact hole. The sixth bridge pattern BRP6 may be connected to a first electrode (ELT1 in FIG. 12) to be described later through a contact hole. Accordingly, the first electrode ELT1 may be connected to the first transistor electrode of the first transistor M1 through the sixth bridge pattern BRP6 and the third capacitor electrode Cst_E3 (and the second bridge pattern BRP2).

The passivation layer PW may be located on the fourth conductive layer SD2. The passivation layer PW may include an insulating material including an inorganic material and/or an organic material. For example, the passivation layer PW may include at least one inorganic film including various currently known inorganic insulating materials including a silicon nitride (SiNx), a silicon oxide (SiOx), or a silicon oxynitride (SiOxNy). Alternatively, the passivation layer PW may include at least one layer of organic film including various organic insulating materials currently known and/or a photo resist film, or may include a single-layered or multi-layered insulator complexly including organic/inorganic materials. That is, the constituent material of the passivation layer PW may be variously changed.

In some embodiments, the passivation layer PW may include an opening exposing the second interlayer insulating layer ILD2. A width of the opening of the passivation layer PW (that is, the width in the first direction (X-axis direction)) may be longer than a length of the light emitting element LD.

In one or more embodiments, the passivation layer PW may have a semi-circular or semi-elliptical cross-section that becomes narrower toward an upper portion thereof. In this case, a side surface of the passivation layer PW may have a curved surface. However, the shape of the passivation layer PW is not limited thereto, and the passivation layer PW may have a trapezoidal cross-section that becomes narrower toward the upper portion thereof. That is, in the present disclosure, the shape of the passivation layer PW is not particularly limited and may be variously changed.

In one or more embodiments, the passivation layer PW may function as a reflective member. For example, the passivation layer PW may function as a reflective member that guides the light emitted from each light emitting element LD in a desired direction together with the first electrode ELT1 and the second electrode ELT2 provided thereon to improve the light efficiency of the first pixel PXL1 (or the pixels).

The first electrode ELT1 and the second electrode ELT2 may be located on the passivation layer PW. The first electrode ELT1 and the second electrode ELT2 may be located to be spaced apart from each other.

The first electrode ELT1 and the second electrode ELT2 may have a shape corresponding to the shape of the passivation layer PW. For example, the first electrode ELT1 and the second electrode ELT2 may respectively have an inclined surface or a curved surface corresponding to the passivation layer PW (for example, a first portion PW_S1 and a second portion PW_S2 of the passivation layer PW), and may respectively protrude in a thickness direction thereof (or the third direction (Z-axis direction).

The first electrode ELT1 overlaps the sixth bridge pattern BRP6, and may be connected to the sixth bridge pattern BRP6 through a contact hole exposing the sixth bridge pattern BRP6. Accordingly, the first electrode ELT1 may be connected to the first transistor electrode of the first transistor M1 through the sixth bridge pattern BRP6 and the third capacitor electrode Cst_E3 (and the second bridge pattern BRP2).

The second electrode ELT2 overlaps the second vertical power line PL2_V, and may be connected to the second vertical power line PL2_V through a contact hole exposing the second vertical power line PL2_V.

Each of the first and second electrodes ELT1 and ELT2 may include at least one conductive material. For example, each of the first and second electrodes ELT1 and ELT2 may include at least one material of a metal such as Ag, Mg, Al, Pt, Pd, Au, Ni, Nd, Ir, Cr, Ti, and an alloy thereof, a conductive oxide such as an ITO, an IZO, a ZnO, and an ITZO, and a conductive polymer such as a PEDOT, but is not limited thereto.

In addition, each of the first and second electrodes ELT1 and ELT2 may be configured of a single layer or multilayer. For example, each of the first and second electrodes ELT1 and ELT2 may include at least one reflective electrode layer. In addition, each of the first and second electrodes ELT1 and ELT2 may selectively further include at least one of at least one transparent electrode layer located at an upper portion and/or a lower portion of the reflective electrode layer and at least one conductive capping layer covering an upper portion of the reflective electrode layer and/or the transparent electrode layer.

A third interlayer insulating layer INS1 may be located on one area of the first and second electrodes ELT1 and ELT2. For example, the third interlayer insulating layer INS1 may be formed to cover one area of the first and second electrodes ELT1 and ELT2, and may include an opening exposing the other area of the first and second electrodes ELT1 and ELT2.

In one or more embodiments, the third interlayer insulating layer INS1 may be first formed to entirely cover the first and second electrodes ELT1 and ELT2. After the light emitting elements LD are supplied and aligned on the third interlayer insulating layer INS1, the third interlayer insulating layer INS1 may be partially opened to expose the first and second electrodes ELT1 and ELT2 at first and second contacts/predetermined first and second contacts. Alternatively, the third interlayer insulating layer INS1 may be patterned in a form of an individual pattern that is locally located under the light emitting elements LD after the light emitting elements LD are completely supplied and aligned.

That is, the third interlayer insulating layer INS1 is interposed between the first and second electrodes ELT1 and ELT2 and the light emitting elements LD, and may expose at least one area of each of the first and second electrodes ELT1 and ELT2. The third interlayer insulating layer INS1 is formed to cover the first and second electrodes ELT1 and ELT2 after the first and second electrodes ELT1 and ELT2 are formed, so that in a subsequent process, it is possible to reduce or prevent the likelihood of the first and second electrodes ELT1 and ELT2 being damaged or a metal being precipitated. In addition, the third interlayer insulating layer INS1 may stably support each light emitting element LD. In some embodiments, the third interlayer insulating layer INS1 may be omitted.

The light emitting elements LD may be supplied and aligned on the third interlayer insulating layer INS1. For example, the light emitting elements LD are supplied through an inkjet method and the like, and the light emitting elements LD may be aligned between the first and second electrodes ELT1 and ELT2 by an alignment voltage/predetermined alignment voltage (or alignment signal) applied to the first and second electrodes ELT1 and ELT2.

A fourth interlayer insulating layer INS2 is located on an upper portion of the light emitting elements LD, for example, the light emitting elements LD aligned between the first and second electrodes ELT1 and ELT2, and may expose the first and second end portions EP1 and EP2 of the light emitting elements LD. For example, the fourth interlayer insulating layer INS2 may not cover the first and second end portions EP1 and EP2 of the light emitting elements LD, and may be partially located on only an upper portion of one area of the light emitting elements LD. The fourth interlayer insulating layer INS2 may be formed in an independent pattern, but is not limited thereto.

The first and second contact electrodes CNE1 and CNE2 may be located on the first and second electrodes ELT1 and ELT2 and the first and second end portions EP1 and EP2 of the light emitting elements LD. In one or more embodiments, the first and second contact electrodes CNE1 and CNE2 may be located on the same layer as shown in FIG. 12. In this case, the first and second contact electrodes CNE1 and CNE2 may be formed by using the same conductive material in the same process.

In one or more other embodiments, the first and second contact electrodes CNE1 and CNE2 may be divided into a plurality of groups to be sequentially formed on different layers for each group. For example, as shown in FIG. 13, a pair of first and second adjacent contact electrodes CNE1 and CNE2 may be sequentially formed on different layers. In this case, a sixth interlayer insulating layer INS4 may be additionally located between the pair of first and second contact electrodes CNE1 and CNE2.

The first and second contact electrodes CNE1 and CNE2 may electrically connect the first and second end portions EP1 and EP2 of the light emitting elements LD to the first and second electrodes ELT1 and ELT2, respectively.

For example, the first contact electrode CNE1 may be located on the first electrode ELT1 to be in contact with the first electrode ELT1. For example, the first contact electrode CNE1 may be located to be in contact with the first electrode ELT1 on one area of the first electrode ELT1 that is not covered by the third interlayer insulating layer INS1. In addition, the first contact electrode CNE1 may be located on the first end portion EP1 so as to be in contact with the first end portion EP1 of at least one light emitting element adjacent to the first electrode ELT1, for example, of each of a plurality of light emitting elements LD. That is, the first contact electrode CNE1 may be located to cover the first end portion EP1 of each of the light emitting elements LD and at least one area of the first electrode ELT1 corresponding thereto. Accordingly, the first end portion EP1 of each of the light emitting elements LD may be electrically connected to the first electrode ELT1.

Similarly, the second contact electrode CNE2 may be located on the second electrode ELT2 to be in contact with the second electrode ELT2. For example, the second contact electrode CNE2 may be located to be in contact with the second electrode ELT2 on one area of the second electrode ELT2 that is not covered by the third interlayer insulating layer INS1. In addition, the second contact electrode CNE2 may be located on the first end portion EP2 so as to be in contact with the second end portion EP2 of at least one light emitting element adjacent to the second electrode ELT2, for example, of each of a plurality of light emitting elements LD. That is, the second contact electrode CNE2 may be located to cover the second end portion EP2 of each of the light emitting elements LD and at least one area of the second electrode ELT2 corresponding thereto. Accordingly, the second end portion EP2 of each of the light emitting elements LD may be electrically connected to the second electrode ELT2.

A fifth interlayer insulating layer INS3 may be formed and/or located on one surface of the substrate SUB on which the passivation layer PW, the first and second electrodes ELT1 and ELT2, the light emitting elements LD, and the first and second contact electrodes CNE1 and CNE2 are formed so as to cover the passivation layer PW, the first and second electrodes ELT1 and ELT2, the light emitting elements LD, and the first and second contact electrodes CNE1 and CNE2. The fifth interlayer insulating layer INS3 may include a thin film encapsulation layer including at least one inorganic and/or organic film, but is not limited thereto. In addition, in some embodiments, at least one overcoat layer may be further located on an upper portion of the fifth interlayer insulating layer INS3.

In some embodiments, each of the third to fifth interlayer insulating layers INS1, INS2, and INS3 may be configured as a single layer or a multilayer, and may include at least one inorganic and/or organic insulating material. For example, each of the third to fifth interlayer insulating layers INS1, INS2, and INS3 may include various types of currently known organic/inorganic insulating materials including a silicon nitride (SiNx), and a constituent material of each of the third to fifth interlayer insulating layers INS1, INS2, and INS3 is not particularly limited. In addition, the third to fifth interlayer insulating layers INS1, INS2, and INS3 may include different insulating materials, or at least some of the third to fifth interlayer insulating layers INS1, INS2, and INS3 may include the same insulating material.

According to the above-described embodiments, the charging capacity of the storage capacitor Cst may be increased by thinly forming the thicknesses of the first interlayer insulating layer ILD1, the gate insulating layer GI, and/or the buffer layer BFL of the first area A1. Accordingly, it is possible to reduce or minimize a capacitance deviation between the gate electrode and the source electrode due to a change in characteristics of the light emitting element LD, and thus, a short-term afterimage defect due to non-uniform luminance may be reduced or minimized. In addition, because a large charging capacity may be secured in a limited space, an area occupied by the storage capacitor Cst may be reduced or minimized. That is, an ultra-high resolution display device may be suitably implemented.

Subsequently, a manufacturing method of the display device according to the above-described embodiments will be described. Among the display devices according to various embodiments, a method of manufacturing the display device of FIG. 14 will be described as an example. Constituent elements substantially the same as those of FIG. 14 are denoted by the same reference numerals, and detailed reference numerals are omitted.

FIG. 18 to FIG. 24 illustrate cross-sectional views of process steps of a manufacturing method of a display device according to one or more embodiments.

Referring to FIG. 18, the substrate SUB is first prepared, and the first conductive layer BML is formed on the substrate SUB. The first conductive layer BML may include one or more of molybdenum (Mo), aluminum (Al), platinum (Pt), palladium (Pd), silver (Ag), magnesium (Mg), gold (Au), nickel (Ni), neodymium (Nd)), iridium (Ir), chromium (Cr), titanium (Ti), tantalum (Ta), tungsten (W), and copper (Cu) to be formed in a single-filmed or multi-filmed structure.

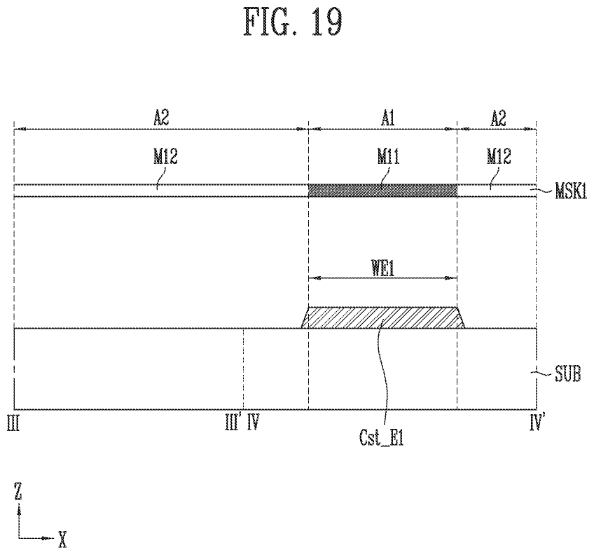

Referring to FIG. 19, next, the first conductive layer BML is patterned by using a first mask MSK1 to form the first capacitor electrode Cst_E1 in the first area A1. The first mask MSK1 may include a light blocking portion M11 corresponding to the first area A1 described above and a light transmitting portion M12 corresponding to the second area A2 described above.

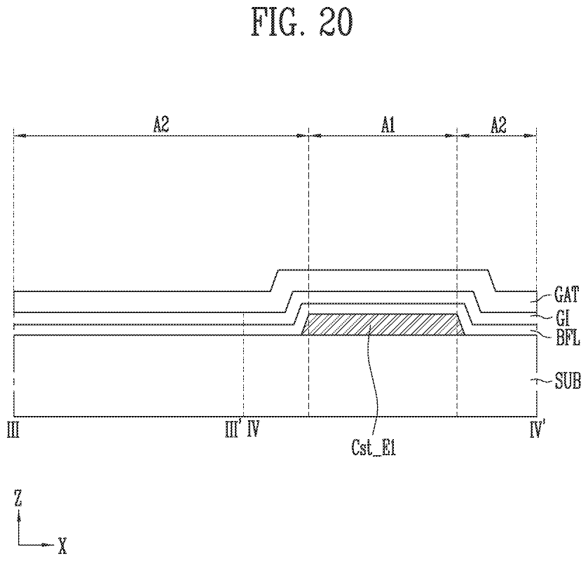

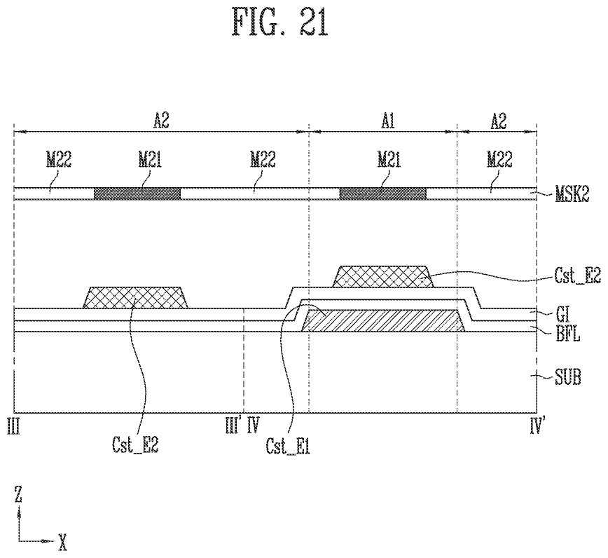

Referring to FIG. 20, next, the buffer layer BFL, the gate insulating layer GI, and the second conductive layer GAT are formed on the first capacitor electrode Cst_E1. The buffer layer BFL and/or the gate insulating layer GI may be formed by a continuous deposition process, but are not limited thereto. The second conductive layer GAT may include one or more of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W), and copper (Cu) to be formed in a single-filmed or multi-filmed structure.

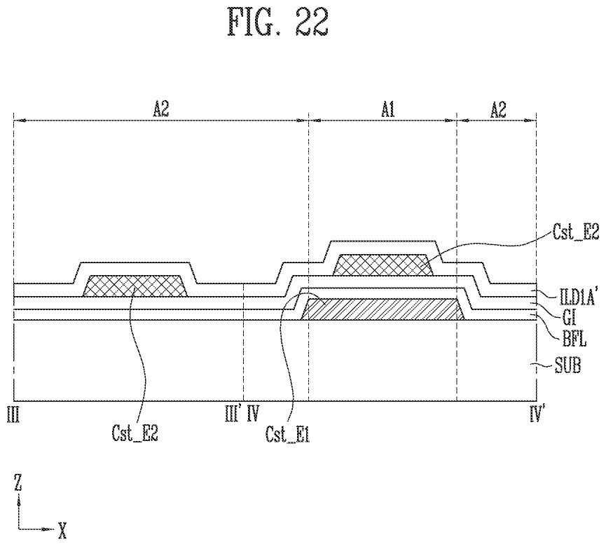

Referring to FIG. 21, next, the second conductive layer GAT is patterned by using a second mask MSK2 to form the second capacitor electrode Cst_E2. The second mask MSK2 may include a light blocking portion M21 and a light transmitting portion M22, and the light blocking portion M21 of the second mask MSK2 may overlap an area in which the second capacitor electrode Cst_E2 is to be formed.

Referring to FIG. 22, next, a first insulating layer ILD1A′ is formed on the second capacitor electrode Cst_E2. The first insulating layer ILD1A′ may be formed of an inorganic insulating material such as a silicon oxide (SiOx), a silicon nitride (SiNx), a silicon oxynitride (SiOxNy), a hafnium oxide (HfOx), an aluminum oxide (AlOx), a titanium oxide (TiOx), a tantalum oxide (TaOx), and a zinc oxide (ZnOx).

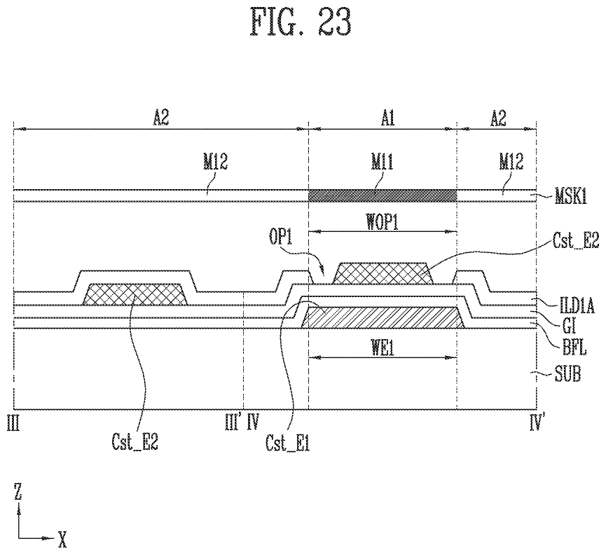

Referring to FIG. 23, next, the first opening OP1 is formed by patterning the first insulating layer (ILD1A′) by using the first mask MSK1 described above. In this case, a width in the first direction (X-axis direction) of the first opening OP1 of the first insulating layer ILD1A may be substantially the same as the width WE1 in the first direction (X-axis direction) of the first capacitor electrode Cst_E1. As described above, by patterning the first opening OP1 of the first insulating layer ILD1A by using the same mask as the mask used to form the first capacitor electrode Cst_E1, the number of the masks may be maintained to reduce the manufacturing cost.

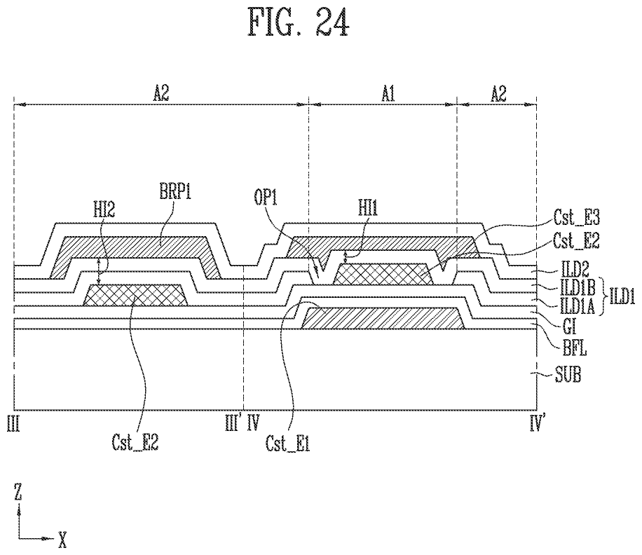

Referring to FIG. 24, next, the second insulating layer ILD1B is formed on the first insulating layer ILD1A. The second insulating layer ILD1B may be formed of an inorganic insulating material such as a silicon oxide (SiOx), a silicon nitride (SiNx), a silicon oxynitride (SiOxNy), a hafnium oxide (HfOx), an aluminum oxide (AlOx), a titanium oxide (TiOx), a tantalum oxide (TaOx), and a zinc oxide (ZnOx). The second insulating layer ILD1B may be directly formed on the second capacitor electrode Cst_E2 exposed by the first opening OP1 of the above-described first insulating layer ILD1A. Due to the first opening OP1 of the first insulating layer ILD1A, the thickness HI1 of the first interlayer insulating layer ILD1 in the first area A1 may be thinly formed, so that the charging capacity of the storage capacitor Cst may be increased in a limited space. Accordingly, as described above, it is possible to reduce or minimize a short-term after-image defect caused by a change in characteristics of the light emitting element LD and to reduce or minimize the area occupied by the storage capacitor Cst, so that it is possible to suitably implement an ultra-high resolution display device. Subsequently, the display device shown in FIG. 14 may be completed by forming the third capacitor electrode Cst_E3 and the second interlayer insulating layer ILD2 on the first interlayer insulating layer ILD1.

Those skilled in the art related to the present disclosure will readily appreciate that many modifications are possible without materially departing from the novel teachings aspects. The embodiments should be considered in a descriptive sense only and not for purposes of limitation. The scope of the present disclosure, not by the detailed description given in the appended claims, and all differences within the equivalent scope will be construed as being included in the present disclosure.

1. A display device comprising:
first and second electrodes spaced apart from each other in a first direction;
light emitting elements located between the first electrode and the second electrode;
a pixel circuit including a capacitor including first to third capacitor electrodes that are sequentially stacked;
an interlayer insulating layer located between the second capacitor electrode and the third capacitor electrode;
a first area overlapping the first capacitor electrode; and
a second area excluding the first area,
wherein a thickness of the interlayer insulating layer in the first area is thinner than a thickness of the interlayer insulating layer in the second area.

2. The display device of claim 1, wherein a width of the first area in the first direction is substantially the same as a width of the first capacitor electrode in the first direction.

3. The display device of claim 2, wherein a width of the first area in the first direction is greater than a width of the second capacitor electrode in the first direction.

4. The display device of claim 2, wherein a width of the first area in the first direction is less than a width of the third capacitor electrode in the first direction.

5. The display device of claim 1, wherein the interlayer insulating layer includes a first insulating layer, and a second insulating layer located above the first insulating layer, and
wherein the first insulating layer defines an opening overlapping the first area.

6. The display device of claim 5, wherein a width of the opening of the first insulating layer in the first direction is substantially the same as a width of the first capacitor electrode in the first direction.

7. The display device of claim 6, wherein a width of the opening of the first insulating layer in the first direction is greater than a width of the second capacitor electrode in the first direction.

8. The display device of claim 5, wherein the opening of the first insulating layer exposes the second capacitor electrode.

9. The display device of claim 8, wherein the second insulating layer is in contact with the second capacitor electrode through the opening of the first insulating layer.

10. The display device of claim 1, wherein the interlayer insulating layer includes a first insulating layer, and a second insulating layer located above the first insulating layer, and
wherein the second insulating layer defines an opening overlapping the first area.

11. The display device of claim 10, wherein the opening of the second insulating layer overlaps the second capacitor electrode.

12. The display device of claim 10, wherein a width of the opening of the second insulating layer in the first direction is substantially the same as a width of the first capacitor electrode in the first direction.

13. The display device of claim 1, further comprising a gate insulating layer located between the first capacitor electrode and the second capacitor electrode,
wherein a thickness of the gate insulating layer in the first area is thinner than a thickness of the gate insulating layer in the second area.

14. The display device of claim 13, wherein the gate insulating layer includes a plurality of inorganic films, and at least one of the inorganic films defines an opening overlapping the first area.

15. The display device of claim 14, wherein a width of the opening of the gate insulating layer in the first direction is substantially the same as a width of the first capacitor electrode in the first direction.

16. The display device of claim 1, wherein the first capacitor electrode is formed of a first conductive layer,
wherein the second capacitor electrode is formed of a second conductive layer, and
wherein the display device further includes a semiconductor layer located between the first conductive layer and the second conductive layer.

17. The display device of claim 1, wherein the first capacitor electrode and the second capacitor electrode overlap to configure a first capacitor, and
wherein the second capacitor electrode and the third capacitor electrode overlap to configure a second capacitor.

18. The display device of claim 1, wherein the pixel circuit includes transistors that drive a respective one of the light emitting elements, and
wherein each of the transistors includes:
a semiconductor layer located in the second area;
a gate electrode located above the semiconductor layer; and
a source electrode and a drain electrode located above the gate electrode and respectively connected to the semiconductor layer.

19. The display device of claim 18, wherein the second capacitor electrode is formed of a same conductive layer as the gate electrode, and
wherein the third capacitor electrode is formed of the same conductive layer as the source electrode and the drain electrode.

20. The display device of claim 18, wherein the capacitor is connected between a node electrically connected to the gate electrode and the first electrode.
